(19) United States
(12) Patent Application Publication
(10) Pub. No.: US 2026/0038541 A1
(43) Pub. Date: Feb. 5, 2026

(54) DUMMY WORD LINE POSITIONING FOR A PLUG FOR PROTECTION OF BACKSIDE SOURCE FORMATION OF VERTICAL PLANAR MEMORY CELLS

(71) Applicant: Micron Technology, Inc., Boise, ID (US)

(72) Inventors: Masaaki Higuchi, Yokohama (JP); Yoshiaki Fukuzumi, Yokohama (JP); Marc Aoulaiche, Boise, ID (US); Matthew J. King, Boise, ID (US)

(21) Appl. No.: 19/267,302

(22) Filed: Jul. 11, 2025

Related U.S. Application Data
(60) Provisional application No. 63/677,539, filed on Jul. 31, 2024.

(51) Int. Cl. G11C 5/06; G11C 16/08; G11C 16/10; G11C 16/24; G11C 16/28; H10B 41/27; H10B 41/35; H10B 43/27; H10B 43/35; H10D 62/13; H10D 62/17

(52) U.S. Cl. CPC G11C 5/063; G11C 16/08; G11C 16/10; G11C 16/24; G11C 16/28; H10B 41/27; H10B 41/35; H10B 43/27; H10B 43/35; H10D 62/151; H10D 62/292

(57) ABSTRACT

Methods, systems, and devices for dummy word line positioning for a plug for protection of backside source formation of vertical planar memory cells are described. A plug structure within a memory system may reduce exposure of portions of the memory system to a source material during a backside source formation process while improving current flow via bit line structures connected to the plug. During the backside source formation, the plug may stop diffused source materials from affecting access lines or other areas of the memory system. The plug may be in contact with a selector and one or more voltage lines configured to activate the bit line structures. The physical positioning of the voltage lines relative to the bit line structures, as well as various magnitudes of voltages applied to the voltage lines during access operations, may increase string current through the plug and bit line structures.

### CROSS REFERENCE

The present Application for Patent claims priority to U.S. Patent Application No. 63/677,539 by Higuchi et al., entitled “DUMMY WORD LINE POSITIONING FOR A PLUG FOR PROTECTION OF BACKSIDE SOURCE FORMATION OF VERTICAL PLANAR MEMORY CELLS,” filed Jul. 31, 2024, which is assigned to the assignee hereof, and which is expressly incorporated by reference in its entirety herein.

### TECHNICAL FIELD

The following relates to one or more systems for memory, including dummy word line positioning within an apparatus for a plug for protection of backside source formation of vertical planar memory cells.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a system that supports dummy word line positioning within an apparatus for a plug for protection of backside source formation of vertical planar memory cells in accordance with examples as disclosed herein.

FIGS. 2A through 2I show examples of memory architectures that support dummy word line positioning within an apparatus for a plug for protection of backside source formation of vertical planar memory cells in accordance with examples as disclosed herein.

FIG. 3 shows an example of a memory architecture that supports dummy word line positioning within an apparatus for a plug for protection of backside source formation of vertical planar memory cells in accordance with examples as disclosed herein.

FIG. 4 shows an example of a memory architecture that supports dummy word line positioning within an apparatus for a plug for protection of backside source formation of vertical planar memory cells in accordance with examples as disclosed herein.

FIG. 5 shows a block diagram of a memory system that supports dummy word line positioning within an apparatus for a plug for protection of backside source formation of vertical planar memory cells in accordance with examples as disclosed herein.

FIG. 6 shows a flowchart illustrating a method or methods that support dummy word line positioning within an apparatus for a plug for protection of backside source formation of vertical planar memory cells in accordance with examples as disclosed herein.

### DETAILED DESCRIPTION

Some memory systems (e.g., apparatuses) include vertical planar memory cells, in which planar cell transistors (e.g., NAND memory cells) may be connected within a trench-like structure, for example, to form a more scaled memory array than some other arrays in which a cylinder-like structure or some other structure may be used for memory cells. A backside source formation process may be used to form a source for one or more of the memory cells by flipping an apparatus over, removing a substrate, and depositing source materials from the back side (e.g., via oxide-nitride-oxide (ONO) etching and poly diffusion). In some vertical planar cell structures, such as trench-shaped structures, there may be some spaces between memory cell pillars. As such, the source material may enter, via the holes, other regions in the apparatus, which may reduce efficiency, reduce control of a voltage threshold of the cell, and reduce reliability overall, among other examples.

In some examples, a plug structure may be formed within an apparatus to reduce exposure of other portions of the apparatus to the source material during a backside source formation process. The plug may be formed within a trench between cell pillars and a corresponding substrate, for example, and may be filled with a polysilicon or other conductive material. The plug may be coupled with one or more bit line structures (e.g., strings including conductive material extending between memory cells connected in series between the plug and a selector) that extend vertically through the stack and access the memory cell pillars. A conductive selector may be coupled with the plug and may be configured to apply a voltage to the plug to induce current flow through the plug and corresponding bit line structures (e.g., gate-inducted drain leakage (GIDL)). However, physical spacing between the conductive plug, the bit line structures, and the conductive selector may produce varying electric field magnitudes at different portions of the plug and the bit line structures, which may affect current flow and corresponding access operations. Additionally, or alternatively, a connection between the conductive plug and the one or more bit line structures may include a relatively sharp corner with one or more portions that protrude into the stack of materials, which may reduce current flow (e.g., GIDL) in the connection, thereby reducing efficiency overall.

Techniques, systems, and devices described herein provide for a combined plug, selector, and voltage line structure within an apparatus to reduce exposure of other portions of the apparatus to the source material during a backside source formation process while improving consistency of an electric field and corresponding current flow via the bit line structures. For example, the plug may be formed between memory cell pillars within the trench and a corresponding substrate. The plug structure described herein may connect to the one or more bit line structures via a connection region having a corner or other curvature that connects between the plug and the one or more bit line structures. During a backside source formation, the diffused source materials may etch a portion of the plug, but may not enter other areas of the apparatus. The plug may be in contact with a selector and one or more voltage lines (e.g., stand-in word lines). The one or more voltage lines may be positioned above the selector relative to a substrate, below the selector relative to the substrate, or both. A distance between each of the one or more voltage lines and the bit line structures may thereby be different from a distance between the selector and the bit line structures. The voltage lines may be positioned such that a width of a memory channel including the bit line structures may be nearly equal to a distance between a top voltage line and the memory channel within a connection region that connects the plug to the bit line structures. Such spacing may improve consistency of the electric field within the bit line structures (e.g., string line, memory channel), thereby improving string current, among other examples. The memory system may apply one or more voltages to the selector and the one or more voltage lines to activate the bit line structures. Various magnitudes of the applied voltages may improve the string current through the connection region between the bit line structures and the plug. The voltage magnitudes may be based on the voltage applied to the selector and distances between each of the selector, the voltage lines, and the bit line structures.

In addition to applicability in apparatuses as described herein, techniques for dummy word line positioning for a plug for protection of backside source formation of vertical planar memory cells may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing an amount of source material, among other materials, that is diffused into an apparatus, thereby improving reliability. Moreover, the shape of the plug described herein to protect against source diffusion as well as the positioning of the voltage lines may reduce resistance and improve current flow within a memory channel, improving throughput and efficiency, among other examples. The described techniques may thereby decrease processing or latency times, improve response times, or otherwise improve user experience, among other benefits.

In addition to applicability in apparatuses as described herein, techniques for dummy word line positioning for a plug for protection of backside source formation of vertical planar memory cells may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing an amount of source material, among other materials, that is diffused into an apparatus, improving reliability of the apparatus, and eliminating or otherwise reducing production processes and complexity while maintaining efficiency, which may result in lowered production emissions, may extend the life of electronic devices and thereby reduce electronic waste, among other benefits.

Features of the disclosure are illustrated and described in the context of systems, devices, and circuits. Features of the disclosure are further illustrated and described in the context of memory architectures and flowcharts.

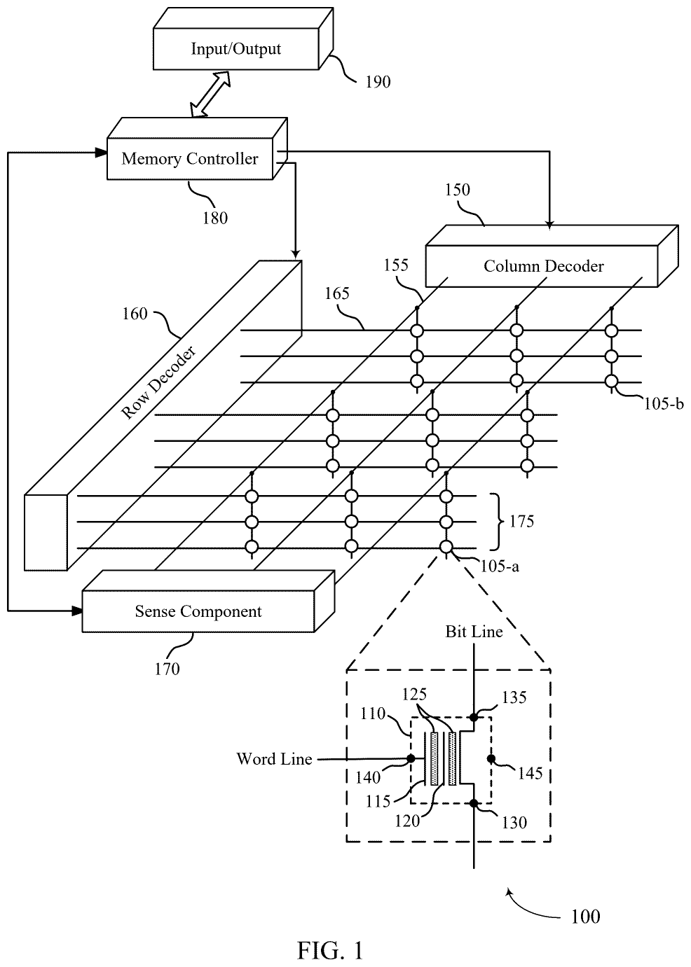

FIG. 1 shows an example of an apparatus 100 (e.g., a memory system) that supports dummy word line positioning for a plug for protection of backside source formation of vertical planar memory cells in accordance with examples as disclosed herein. FIG. 1 is an illustrative representation of various components and features of the apparatus 100. As such, the components and features of the apparatus 100 are shown to illustrate functional interrelationships, and not necessarily physical positions within the apparatus 100. Further, although some elements included in FIG. 1 are labeled with a numeric indicator, some other corresponding elements are not labeled, even though they are the same or would be understood to be similar, in an effort to increase visibility and clarity of the depicted features.

The apparatus 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

In some cases, an apparatus 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, apparatus 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105.

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of apparatus 100.

Some apparatuses include vertical planar memory cells, in which planar cell transistors may be connected within a trench-like structure to form a more scaled memory array than some other arrays in which a cylinder-like structure or some other structure may be used for memory cells. The planar cell transistors may be connected in a vertical direction (e.g., height, stacked). Scaling a width of the cell (e.g., AA width) and a cell-to-cell distance (e.g., a pitch, or AA-to-AA distance) may be a cell size scaling vector.

A backside source formation process may be used to form a source for one or more of the memory cells by flipping an apparatus over, removing a substrate, and depositing source materials from the back side (e.g., via oxide-nitride-oxide (ONO) etching and poly diffusion). In some vertical planar cell structures, such as trench-shaped structures, there may be some spaces between memory cell pillars. As such, the source material may enter, via the holes, other regions in the apparatus, which may reduce efficiency, reduce control of a voltage threshold of the cell, and reduce reliability overall, among other examples. For example, when creating a source gate selector (SGS) using a backside contact that attached the wafer (e.g., substrate) to the vertical planar cell, a chemical solution that etches the insulator film may enter between split memory channels (e.g., doped hollow channels), which may increase difficulty in adjusting a position of an n+ layer. Additionally, or alternatively, the chemical liquid that gets inside the cell structure may damage the cell. In some examples, an n+ poly-silicon may enter the cell side and reduce a threshold voltage of the cell.

As described herein, the apparatus 100 may be formed with a plug structure to reduce exposure of other portions of the apparatus 100 to the source material during a backside source formation process. That is, the SGS structure described herein may provide for a realization of vertical planar cell structures to achieve cell size reduction. The SGS structure described herein may reduce over wet etching during oxide-nitride-oxide films in a memory channel. For example, the plug may be formed between memory cell pillars within the trench and a corresponding substrate. The plug structure described herein may include a connection region that connects the plug to one or more bit line structures. The connection region may have one or more corners or curves to reduce resistance and improve current flow through a memory channel. For example, the plug may be filled with a conductive material (e.g., polysilicon or some other material) to protect the source material from entering via any spaces between memory cell pillars. The plug may include a first rectangular portion that extends along and underneath the trench including multiple memory cell pillars (e.g., a rectangular prism of conductive material). The plug may include a second connection portion on top of the first rectangular portion. The second portion may be U-shaped, double-U shaped, L-shaped, or some other curved or cornered shape and may connect the plug to one or more bit line structures that extend vertically within the apparatus 100 between the plug and one or more bit lines 155 (e.g., digit lines). Each memory cell pillar (e.g., string) may thereby include a respective bit line structure (e.g., channel of conductive material) that is in contact with the same plug of conductive material via curved connections.

The plug may be coupled with one or more voltage lines and a selector. During access operations, various voltages may be applied to the plug via the one or more voltage lines and the selector to induce current flow via the bit line structures. The magnitudes of the applied voltages, as well as the physical positioning of the voltage lines and selector, may reduce resistance and improve current flow via the bit line structures, thereby improving reliability and efficiency, among other examples.

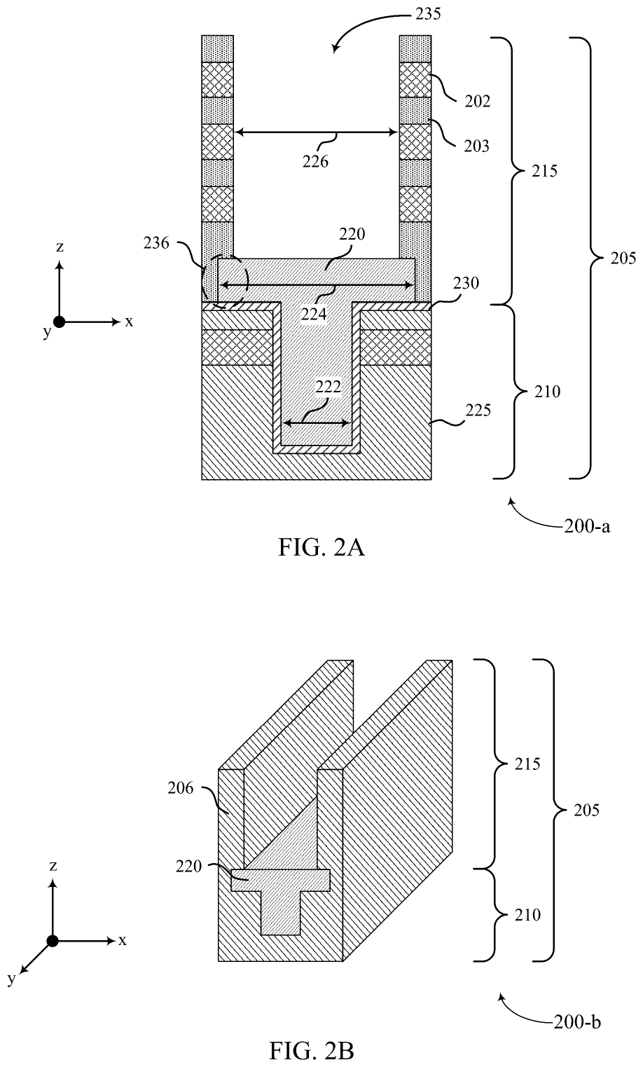

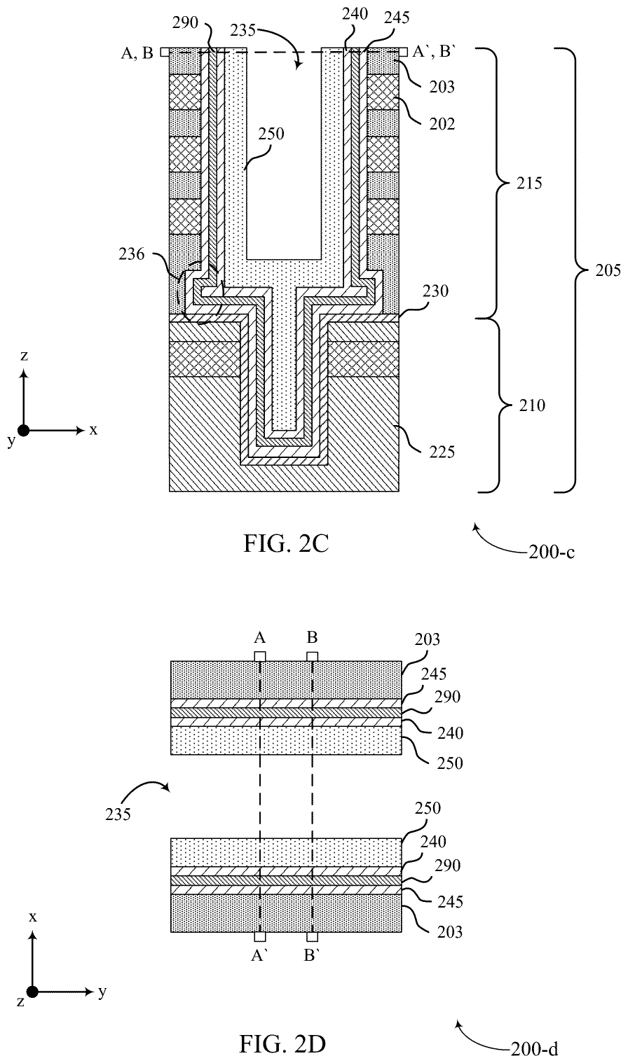

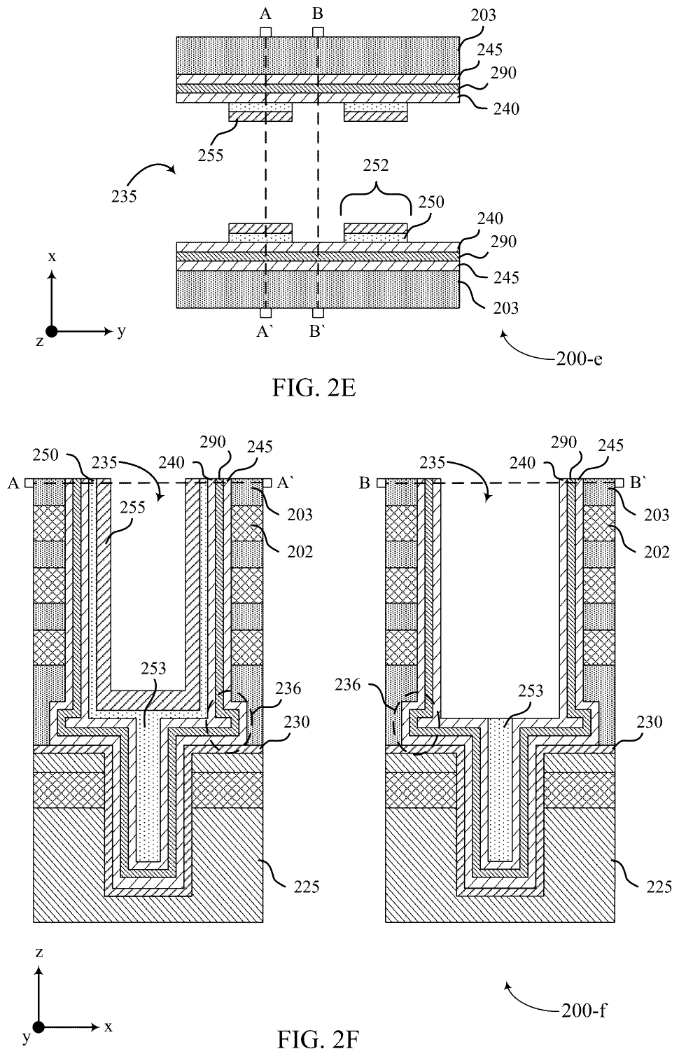

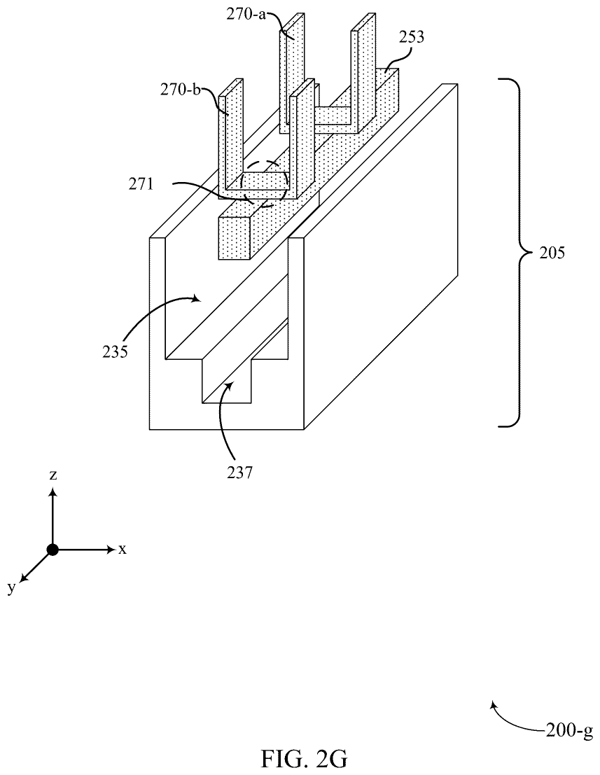

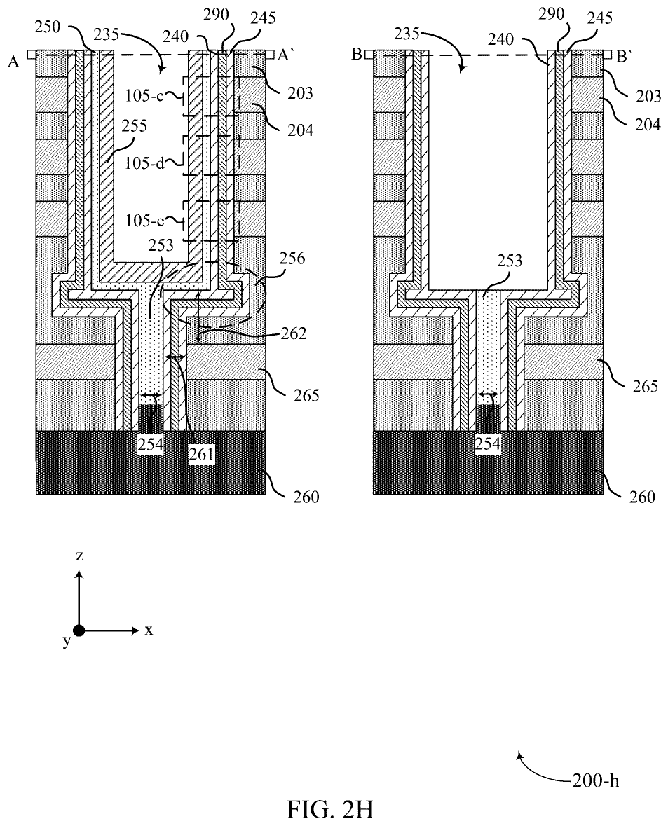

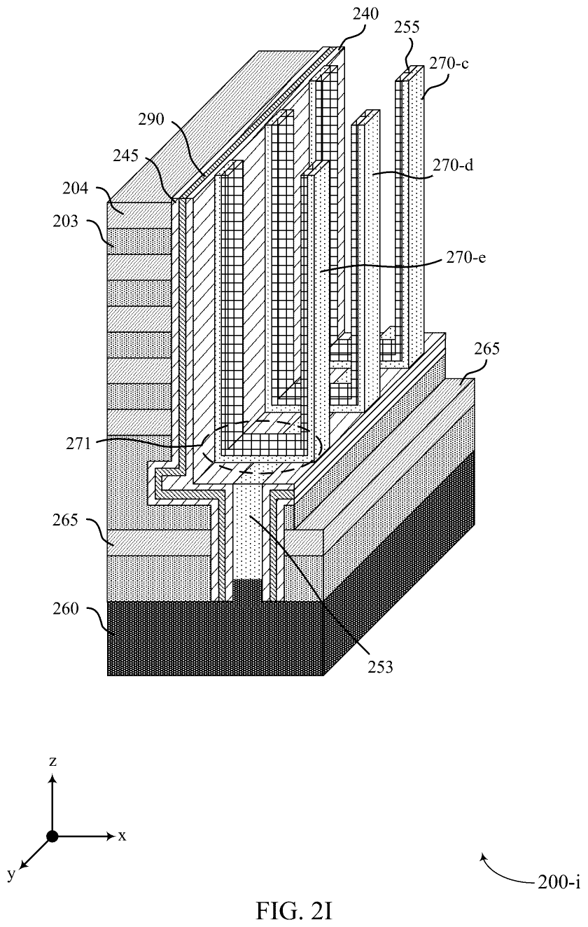

FIGS. 2A through 2I show example of memory architectures 200 that support dummy word line positioning for a plug for protection of backside source formation of vertical planar memory cells in accordance with examples as disclosed herein. The memory architectures 200 may be an example of a portion of an apparatus (e.g., a memory system), such as an apparatus 100. FIGS. 2A through 2I show various views (e.g., diagonal or trimetric views, planar views, other views) of a memory architecture 200, which may be an example of a memory architecture implemented by an apparatus 100, as described with reference to FIG. 1. The memory architectures 200 may illustrate operations associated with forming an apparatus including memory cells across one or more levels of the apparatus that are connected with respective bit lines. Performing the processing steps may consolidate processing steps otherwise associated with forming a memory architecture. For example, the processing steps may support reduced diffusion of a source material to unnecessary regions of an apparatus, among other advantages.

For illustrative purposes, aspects of the memory architecture may be described with reference to an x-direction, a y-direction, and a z-direction of the illustrated coordinate systems. For example, memory architectures 200-b, 200-g, and 200-i illustrate the memory architecture from trimetric views, where a substrate of the memory architecture may be associated with an xy-plane, and where the memory architecture extends a distance along the z-direction. Additionally, the memory architectures 200-a, 200-c, 200-d, 200-e, 200-f, and 200-h, may illustrate the memory architecture with a cross-sectional and/or planar view, such that a portion of the memory architecture may be removed from the trimetric view to illustrate a cross-section of the memory architecture in the xz-plane, the xy-plane, or both. Although the memory architectures 200 illustrate examples of relative dimensions and quantities of various features, aspects of the memory architectures 200 may be implemented with other relative dimensions or quantities of such features in accordance with examples as disclosed herein. In the following description of the processing steps, some methods, techniques, processes, and operations may be performed in different orders or at different times. Further, some operations may be left out of the processing steps, or other operations may be added to the processing steps. Although described as singular processing steps, it is to be understood that each processing step may include one or more multiple processing operations, including, but not limited to, formations, depositions, etches, removals, exhumes, other processing steps, or the like.

Processing steps illustrated in and described with reference to FIGS. 2A through 2I may be performed by a manufacturing system, such as a semiconductor fabrication system configured to perform additive operations such as deposition, formation, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

FIG. 2A illustrates an example of a memory architecture 200-a after a first processing step associated with forming a stack of materials 205 and a sacrificial plug 220. For example, forming the stack of materials 205 may include depositing alternating (e.g., or at least partially alternating) layers of an oxide material 203 and a sacrificial material 202 above a substrate (e.g., a plane or sheet in the xy-plane on which subsequent memory materials may be formed. The substrate may be associated with complementary metal-oxide semiconductor (CMOS) circuitry. In some such examples, depositing the alternating layers may include depositing a layer of the oxide material 203, then depositing a layer of the sacrificial material 202 above the layer of the oxide material 203. Accordingly, the sacrificial material 202 and the oxide material 203 may be similarly deposited to form alternating layers, where the height of the stack of materials 205 may be based on the quantity and height of each of the alternating layers. In some implementations, the oxide material 203 may be a dielectric material, such as silicon oxide, silicon oxycarbide, silicon oxynitride, or silicon nitride. In some implementations, the sacrificial material 202 may be a variation of nitride.

In some examples, the stack of materials 205 may be formed in two or more formation processes. For example, the first level 210 may be formed first, and the second level 215 may be formed after formation of the first level 210. Forming the first level 210 may include depositing one or more layers of an oxide material 225 and one or more layers of the sacrificial material 202. The oxide material 225 may be the same as or different from the oxide material 203 in the second level 215. In some examples, after the first level 210 is formed, the first level 210 may be etched to form a first cavity (not pictured in FIG. 2A) having a first width 222. The first cavity may pass through the first level 210 of the stack of materials 205 in a first direction (e.g., vertical, the z-direction) and a second direction (e.g., horizontal, the y-direction), having a width 222 in a third direction (e.g., the x-direction). The first cavity may not extend fully through the first level 210, such that a portion of oxide material 225 may remain between the first cavity and a substrate, in some examples. The first cavity may be filled with a sacrificial material 230, which may be an oxide material, such as the oxide material 203, or some other material. The second level 215 may then be formed on top of the first level 210 including the cavity filled with the sacrificial material 230. In some examples, as illustrated in FIG. 2A, the sacrificial material 230 may form a liner between the first level 210 and a first layer of oxide material 203 in the second level 215.

After forming the second level 215 of the stack of materials 205, one or more other cavities may be formed. For example, a second cavity 235 may be formed in the second level 215 of the stack of materials 205. The second cavity 235 may be above the first cavity relative to the substrate. The second cavity 235 may pass through the second level 215 of the stack of materials 205 in the first direction (e.g., the z-direction) and the second direction (e.g., the y-direction). The first cavity and the second cavity 235 may be formed via respective etch processes in which materials are removed from the stack of materials 205 to form the cavities. The first cavity may be formed with a first width 222 and the second cavity 235 may be formed with a second width 226, where the second width 226 is greater than the first width 222.

In some examples, a recess 236 may be formed within the stack of materials 205 between the first cavity and the second cavity 235. For example, a portion of a first layer of oxide material 203 in the second level 215 of the stack of materials 205 may be etched to form a recess 236 (e.g., on each side of the stack) that expands a width of the second cavity 235 from the second width 226 to a third width 224 that is greater than the first width 222 and the second width 226.

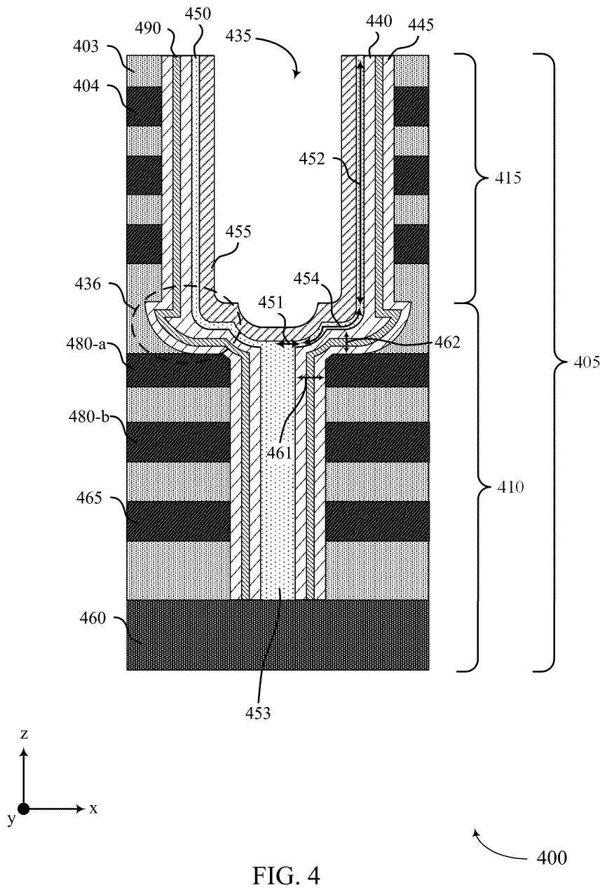

After forming the stack of materials 205 and the various cavities, a sacrificial plug 220 may be formed within the first cavity and the recess 236. For example, a sacrificial plug material may be deposited within the first cavity and the recess 236 to form the sacrificial plug 220. In some examples, the formation of the sacrificial plug 220 may form the recess 236 (e.g., the sacrificial plug material may etch back or recede a portion of the oxide material 203). Additionally, or alternatively, the sacrificial plug 220 may be formed within the first cavity before formation of the second level 215, and the second level 215 may be formed on top of the sacrificial plug 220. The sacrificial plug 220 may be a T-shaped plug, or some other shape having the first width 222 in the first level 210 of the stack and the third width 224 in the second level 215 of the stack. In some examples (not pictured in FIG. 2A), the sacrificial plug 220 may have a U-shape or a double U-shaped top portion, for example, the portion of the sacrificial plug 220 that is within the first level 210 may be rectangular (e.g., a rectangular prism), but the portion within the second level 215 may be U-shaped or double U-shaped, which may result in a rounded structure, similar to the structure illustrated in FIG. 4, for example.

FIG. 2B illustrates an example of a memory architecture 200-b after the first processing step associated with forming the sacrificial plug 220 within the stack of materials 205. For example, the memory architecture 200-b illustrates a trimetric view (e.g., a diagonal view) of the stack of materials 205 illustrated in FIG. 2A. For clarity, some features of the stack of materials 205 are not illustrated in FIG. 2B. For example, the material 206 may be a simplified representation of the alternating layers of materials, including the oxide material 203 and the sacrificial material 202, as described with reference to FIG. 2A.

As illustrated in FIG. 2B, after the sacrificial plug 220 is formed, the stack of materials 205 may represent a trench-shape, where the sacrificial plug 220 may be a T-shape that extends horizontally (e.g., in the y-direction) through the stack of materials 205 and further extends vertically (e.g., in the z-direction) in a portion of the first level 210 and a portion of the second level 215. The sacrificial plug 220 may additionally, or alternatively, follow some rounded shape, in which a top portion of the plug (e.g., positioned above the rectangular prism in the first level 210) may be rounded or otherwise curved.

FIG. 2C illustrates an example of a memory architecture 200-c after a second processing step associated with forming various layers of materials within the stack of materials 205. For example, the sacrificial plug 220 may be removed (e.g., etched, exhumed) from the stack of materials 205, and one or more layers of materials may be deposited or formed within the first cavity, the recess 236, and the second cavity 235 after the sacrificial plug 220 is removed. The layers of materials may include, for example, a first protective liner 245, a storage material 290, and a second protective liner 240. The materials may be deposited and subsequently etched back to form liners that extend along sidewalls of the stack of materials 205. For example, the first protective liner 245 may extend along sidewalls of the stack of materials 205 within the first cavity, within the recess 236, and within the second cavity 235. The storage material 290 may extend along the first protective liner 245 and between the first protective liner 245 and the second protective liner 240. In some examples, the second protective liner 240 may be deposited and subsequently etched such that a shape of the second protective liner 240 may generally be a U-shape within the second level 215. That is, the second protective liner 240 may include, in some examples, fewer or no curves within the recess 236 than the first protective liner 245 and/or the storage material 290.

After the first protective liner 245, the storage material 290, and the second protective liner 240 are formed, a conductive material 250 may be formed (e.g., deposited) over the second protective liner 240 within a remainder of the first cavity and a portion of the second cavity 235. The conductive material 250 may be associated with one or more bit line structures of the apparatus. A size of the second cavity 235 after these depositions of materials may be reduced as compared with the size of the second cavity 235 in FIG. 2A. The conductive material 250 may thereby fill the first cavity, such that the first level 210 is filled with materials. The conductive material 250 may, in some examples, be formed in the shape of a football field goal post, or a rectangular U-shape connected to a vertical post.

The shape of the materials, including the conductive material 250, may conform to a shape of the cavities level by the sacrificial plug 220. For example, if the sacrificial plug 220 has a rounded U-shape or a rounded double U-shape, as described with reference to FIG. 2A, the resulting shape of the conductive material 250 may be rounded (e.g., may not include sharp corners or angles).

FIG. 2D illustrates an example of a memory architecture 200-d after the second processing step described with reference to FIG. 2C. For example, FIG. 2D illustrates the stack of materials 205 from a birds-eye view (e.g., in the xy-plane). The memory architecture 200-d shown in FIG. 2D illustrates a cross-sectional view of the memory architecture 200-c shown in FIG. 2C, as cut across the A-A′ and B-B′ cross-sectional lines.

As shown in FIG. 2D, after the various materials are formed, a top layer of the apparatus may include two sets of material segments. Each set of material segments including the oxide material 203, the first protective liner 245, the storage material 290, the second protective liner 240, and the conductive material 250. The two sets of materials may be sandwiched together with a space (e.g., the second cavity 235) in between the two sets of materials.

Although not pictured in FIG. 2D, it is to be understood that the second cavity 235 may extend some distance into the page in the z-direction, and there may be more conductive material 250 after the distance, as illustrated in FIG. 2C.

FIG. 2E illustrates an example of a memory architecture 200-e after a third processing step associated with etching back the conductive material 250. The memory architecture 200-e illustrates a birds-eye view of the stack of materials 205 (e.g., in the xy-plane). For example, the memory architecture 200-e illustrates a cross-sectional view of the memory architectures 200-f shown in FIG. 2F, as cut across the A-A and B-B′ cross-sectional lines.

The third processing step may include, for example, depositing a channel oxide material 255 within the second cavity 235. The channel oxide material 255 may be formed on top of the conductive material 250 and may be formed with a threshold thickness or may be etched back, such that the channel oxide material 255 has a relatively constant thickness within the second cavity 235. In some examples, the formation of the channel oxide material 255 may reduce a thickness of the conductive material 250 within the second cavity 235, as illustrated in FIG. 2E.

The third processing step may further include etching the conductive material 250 and the channel oxide material 255. The etching may be performed using a mask, which may cover some portions of the stack of materials and expose other portions. The conductive material 250 and the channel oxide material 255 within the exposed portions may be removed (e.g., etched, exhumed, or the like). There may be remaining segments 252 of conductive material 250 within the second cavity 235 (e.g., a trench). The conductive material 250 may be etched such that each segment 252 of conductive material is separated from (e.g., not in direct physical contact with) any other segment 252 of the conductive material within the second level 215 of the stack. The channel oxide material 255 may be etched to a similar or the same shape as the conductive material 250. In some examples, the channel oxide material 255 may be formed on top of the conductive material 250 after the etching. Additionally, or alternatively, the channel oxide material 255 may be formed prior to the etching.

FIG. 2F illustrates an example of a memory architecture 200-f after the third processing step described with reference to FIG. 2E. The memory architecture 200-f represents an example of the memory architecture 200-e illustrated in FIG. 2E, but from a horizontal view (e.g., in the xz-plane). The memory architecture 200-f may represent cross sectional views of the memory architecture 200-e when cut across the A-A and B-B′ cross-sectional lines.

When cut across the A-A′ cross-sectional line, the memory architecture 200-f may include each of the first protective liner 245, the storage material 290, and the second protective liner 240 extending along sidewalls of the stack of materials 205. The memory architecture 200-f may further include the conductive material 250 within the first level 210 and the second level 215 (e.g., within the second cavity 235). The channel oxide material 255 may further be included within the A-A′ cross-sectional view as a rectangular U-shape (e.g., or a curved U-shape) on top of the conductive material 250 in the second cavity 235. The conductive material 250 within the first level 210 of the stack may be referred to as a plug 253 herein. For example, the plug 253 may include all of the conductive material 250 that extends continuously in the y direction through the stack of materials 205 (e.g., to form a trench-shape). The conductive material 250 that extends from the plug 253 vertically within the second level 215 may be referred to as the segments 252. Thus, when the memory architecture 200-c illustrated in FIG. 2E is cut across the areas that include the segments 252, the conductive material 250 and the channel oxide material 255 are present within the second cavity 235.

However, when cut across the B-B′ cross-sectional line, the view of the memory architecture 200-f may not include the channel oxide material 255 and may not include the conductive material 250 along the sidewalls of the second cavity 235. For example, because of the etching performed in the third processing step, the conductive material 250 may be formed in U-shaped segments (e.g., rectangular U-shaped segments) within the second cavity 235, where the segments 252 extend from the plug 253 horizontally (e.g., in the x-direction) to a sidewall of the second cavity 235 (e.g., to the second protective liner 240), and then vertically (e.g., in the z-direction) along the sidewall of the second cavity 235 (e.g., along the second protective liner 240). The segments 252 may, in some examples, be formed in rounded U-shapes or rounded double U-shapes as described herein. The segments 252 may not, however, extend continuously in the x-direction. Instead, the segments 252 may have a threshold thickness in the x-direction due to the etching. In between the segments 252 may be some other insulating material or an absence of material (e.g., air), at least for part of the manufacturing process. As such, the cross-sectional view of the B-B′ cross-section may not include any conductive material 250 extending from the plug 253 and may instead include the plug 253 that terminates at the second cavity 235.

In some examples, the plug 253 may include a pillar of oxide material within the plug 253 (not pictured in FIG. 2F). For example, an oxide material may be deposited within a recess or cavity in the conductive material 250. That is, the conductive material 250 may not fill the first cavity 237 completely. The remaining space may be filled with the oxide material, creating a pillar that is at least partially surrounded by the conductive material 250. The conductive material 250 may be in contact with at least two sidewalls of the oxide pillar.

FIG. 2G illustrates an example of a memory architecture 200-g in accordance with an abstracted trimetric view after the third processing step described herein. The memory architecture 200-g is abstracted to improve clarity and highlight the shape of the plug 253 and corresponding bit line structures 270 (e.g., bit line structures 270-a and 270-b), each of which may include the conductive material 250 described with reference to FIGS. 2A through 2F. The plug 253 and the bit line structures 270 may be removed from the stack of materials 205 for illustration purposes only, and it is to be understood that the plug 253 may be within the first cavity 237 and the bit line structures 270 may be within the second cavity 235, as described and illustrated with reference to FIGS. 2A through 2F.

As illustrated in FIG. 2G, the plug 253 may be a rectangular or cubic shape that extends in the y-direction (e.g., horizontally) within a trench formed by the first cavity 237 in the first level of the stack of materials 205. The plug 253 may have a first thickness in the x-direction and a second thickness in the z-direction, where the first and second thicknesses may be the same or different. The plug 253 may provide a continuous and solid base connection point for each of the bit line structures 270, which may protect against a source material being diffused throughout the memory architecture 200-g. The bit line structures 270 may be in direct physical contact with the plug 253 at a base contact region 271 and may otherwise be separated from one another. For example, the bit line structure 270-a may not be in direct physical contact with the bit line structure 270-b. There may be an absence of material or some insulating material between the two bit line structures 270-a and 270-b in the y-direction. The bit line structures 270 may each extend horizontally in the x-direction from the base contact region 271 to sidewalls of the second cavity 235 and may extend vertically in the z-direction within the stack of materials 205 and along sidewalls of the second cavity 235. The bit line structures 270 may be configured as bit lines that may active or select one or more memory cells within the stack (e.g., memory cell pillars). Additionally, or alternatively, the bit line structures 270 may represent examples of conductive lines (e.g., strings) of memory cells 105 coupled between two selectors. For example, the bit line structures 270 may represent a conductive channel between memory cells 105. A bit line may be coupled with a top portion of the bit line structures 270 via a selector, such as a select gate drain selector, a select gate source selector, or some other type of selector. In some examples, a connection between the bit line structures 270 and the plug 253 may be referred to as a selector (e.g., a source side selector, among other examples) and may include a first portion. Each bit line structure 270 may include a first string including a first selector with a first portion and a second string including a second selector with a second portion, where the first and second selectors are coupled with the plug 253. Although rectangular bit line structures 270 are illustrated, it is to be understood that the bit line structures 270 may have rounded or otherwise curved shapes, in some examples described herein.

FIG. 2H illustrates an example of a memory architecture 200-h after a fourth processing step associated with metallization and backside source formation. The memory architecture 200-h illustrates cross-sectional views along the A-A and B-B′ cross-sectional lines as described with reference to FIGS. 2E and 2F.

As part of the fourth processing step, a metallization process may be performed to convert the sacrificial material 202 to the metal material 204. The stack of materials may thereby include layers of the oxide material 203 and layers of the metal material 204. The metallization may not alter the structure of the first protective liner 245, the second protective liner 240, the storage material 290, the plug 253, the conductive material 250, or the channel oxide material 255. The plug 253 may have a thickness 254.

The fourth processing step may further include a backside source formation process, in which the source 260 is formed. In some examples, a substrate may be positioned beneath the memory architecture 200-f illustrated in FIG. 2F. As part of the backside source formation, the apparatus may be flipped or otherwise rotated and the substrate may be removed such that the manufacturing system may access a “backside” of the apparatus, which may correspond to a bottom of the first level 210 of the stack of materials 205.

A source material may be deposited from the backside of the apparatus to form the source 260. The source material may include an n+ poly-silicon material, some other material, or any combination thereof. The source material deposition may, in some examples, result in phosphorous diffusion, which may degrade a portion of the plug 253 (e.g., in the vertical or z-direction), but may not degrade or otherwise remove all of the plug 253 due to the plug 253 having sufficient thickness 254. As such, the plug 253 may remain during the backside source formation and the source 260 may be in contact with the plug 253 across the entire or most of the thickness 254 (e.g., over a full surface of the plug 253). The source 260 may thereby be formed without any materials entering the second cavity 235 or other unintended areas of the apparatus. Because the plug 253 extends along the y-direction, even in regions of the apparatus where the bit line structures were removed due to etching, the entire structure is protected from the backside source diffusion, including those areas that do not include bit line structures. For example, as illustrated in the B-B cross-sectional view of the memory architecture 200-h, the second cavity 235 may not include any of the source material after the formation of the source 260 because the plug 253 may stop the diffusion of the source material elsewhere in the structure.

The layers of metal material 204 may be word lines configured to access memory cells 105-c, 105-d, and 105-e within the respective layer. For example, a memory cell 105 may be formed at each junction of the storage material 290 with a respective layer of the metal material 204 and a respective bit line structure including the conductive material 250. The memory cells 105-c, 105-d, and 105-e illustrated in FIG. 2H may be included in a memory cell pillar, in some examples. The memory cell pillars may be referred to as strings, in some examples (e.g., multiple memory cells 105 connected in series). Although not illustrated, it is to be understood that three more memory cells 105 may be included in the other side of the A-A′ cross-sectional view of the memory architecture 200-h.

A given memory cell 105 may be accessed by activation of both a corresponding word line and a corresponding bit line structure at the same time. The activation of the word lines (e.g., the metal material 204) may be controlled via one or more word line decoders or other circuitry, which may be positioned under the array (e.g., within a substrate or elsewhere in the memory architecture 200-g). The activation of the bit line structures may be controlled via a transistor or other selection circuitry, which may include the plug 253, the source 260, and the selector 265. For example, a voltage may be applied via the source 260, and the voltage that passes through to the plug 253 and corresponding bit line structures may be controlled by the selector 265 (e.g., a gate at least partially surrounding the plug 253, an electrode). The voltage may be referred to as a threshold voltage, in some examples. The selector 265 may be relatively close to the source 260 (e.g., closer than the other layers of the metal material 204 to the n+ diffusion point), which may provide for more accurate and reliable control of the threshold voltage (e.g., a gate-source voltage) and corresponding current through the conductive material 250 than if the selector 265 is positioned a further distance from the source 260. In some examples, the bit line structures 270 may represent examples of string lines, and one or more bit lines may extend in the y-direction above the stack of materials 205. The one or more bit lines may be coupled with the bit line structures 270 via one or more other selectors.

In some examples, the sharp corners of the various materials within the connection region 256 between the plug 253 and the bit line structures may increase resistance within a memory channel. For example, a resistance of the bit line structures may be increased due to the sharp corners, which may decrease string current overall, thereby reducing reliability and performance of the apparatus, in some examples. The materials within the connection region 256 may be protruding into the stack of materials 205, in some examples, thereby reducing GIDL at the corner and protruding portions.

Additionally, or alternatively, a first distance 261 between the selector 265 and the plug 253 may be different from (e.g., less than) a second distance 262) between the selector 265 and the conductive material 250 within the bit line structures. The difference in these distances may produce varying magnitudes of an electric field within the plug 253 and the bit line structures. For example, the electric field may be relatively weak within the bit line structures (e.g., in the connection region or selector between the plug 253 and the bit line structures) or may be relatively strong within the plug 253. The varying electric field magnitudes may reduce current flow, increase resistance, and reduce efficiency overall, among other examples.

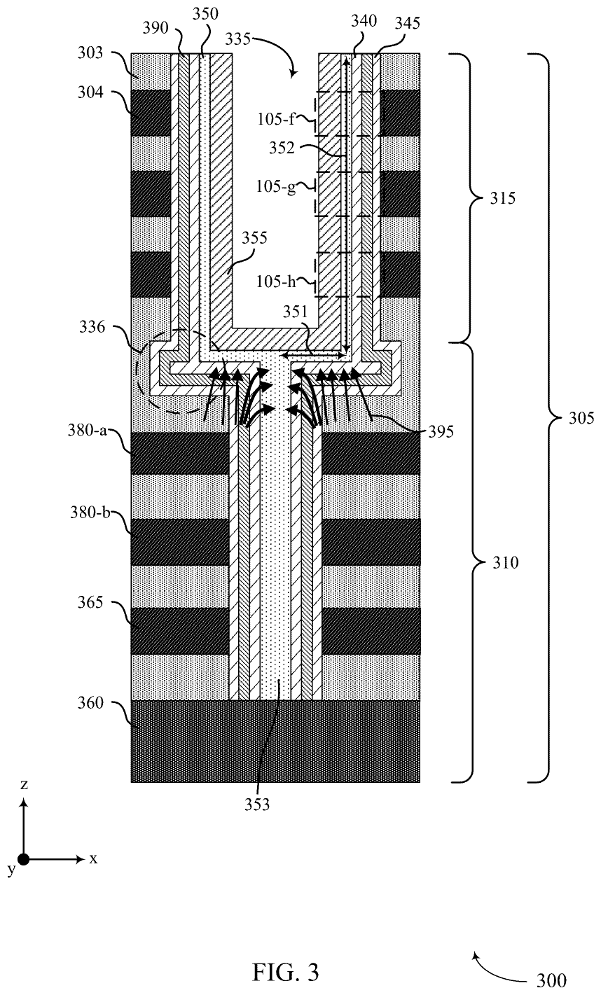

Techniques described herein provide for a plug structure that protects against backside source diffusion while maintaining efficient and reliable current flow via the bit line structures. For example, one or more voltage lines as described herein may be positioned above or otherwise around the selector 265. The voltage lines may be configured to apply one or more voltages to the plug 253, which may improve the electric field consistency (e.g., by equalizing the first distance 261 with a third distance (not pictured) between a voltage line and the bit line structures), and may improve current through the protruding connection region, among other examples. The voltage lines are described and illustrated in further detail elsewhere herein, including with reference to FIGS. 3 and 4.

FIG. 2I illustrates an example of a memory architecture 200-i after the fourth processing step described herein. The memory architecture 200-i illustrates the memory architecture 200-h from a trimetric viewpoint. That is, a portion of the architecture in the y-direction is further shown in FIG. 2I to further illustrate the bit line structures 270 (e.g., bit line structures 270-c, 270-d, and 270-e) and the spacing between them in more detail than shown in the previous figures.

The source 260 may be formed across a bottom of the structure and may be in contact with a surface of the plug 253 in the x-and y-directions. The selector 265 may include the metal material 204 and may extend along the x-and y-directions around the plug 253. That is, the first protective liner 245, the second protective liner 240, and the storage material 290 may be positioned on each side of the plug 253 between the plug 253 and the selector 265. The protective liners 245 and 240, as well as the storage material 290, may continue to extend vertically through the stack. Multiple memory cells 105 may be formed at junctions of the storage material 290, the word lines (e.g., the layers of the metal material 204) and the bit line structures 270, as described and illustrated in FIG. 2H.

The bit line structures 270 may represent rectangular or curved U-shaped segments or curved double U-shaped segments that extend from the plug 253. For example, each bit line structure 270 may be in contact with (e.g., coupled with) the plug 253 at a respective base contact region 271. The bit line structure 270 may extend horizontally (e.g., or along some curvature in a horizontal and vertical direction) on each side of the base contact region 271. The bit line structure 270 may extend vertically from the horizontal segments on each side of the base contact region 271 and along sidewalls of the stack of materials including the oxide material 203 and the metal material 204 (e.g., word lines). In some examples, a channel oxide material 255 may be positioned on top of the bit line structures 270. Each bit line structure 270 may be physically separated from (e.g., independent from, not in contact with) each other bit line structure 270. For example, the bit line structure 270-c may not be in direct contact with the bit line structure 270-d or the bit line structure 270-e outside of the base contact regions 271 at which each of the bit line structures 270 contacts the plug 253. In some examples, a region where a bit line structure 270 extends vertically along the second protective liner 240 and corresponding storage material 290 may be referred to as a memory cell pillar, as there may be multiple memory cells 105 stacked in that area (e.g., at each layer of the metal material 204).

As described with reference to FIG. 2H, the selector 265 may be configured to adjust, based on a voltage applied to the selector 265, a current that flows through the plug 253 and corresponding bit line structures 270 from the source 260. The apparatus may thereby select one or more memory cells 105 by activating, using the source 260 and the selector 265, the bit line structures 270-c, 270-d, and 270-c, and activating one or more of the word lines (e.g., the layers of the metal material 204) that are at the same level as the target memory cell(s) 105.

In some examples, the sharp corners of the various materials within the contact region 271 between the plug 253 and the bit line structures 270 may increase resistance within a memory channel. For example, a resistance of the bit line structures may be increased due to the sharp corners, which may decrease string current overall, thereby reducing reliability and performance of the apparatus, in some examples. The materials within the contact region 271 may be protruding into the stack of materials 205, in some examples, thereby reducing GIDL at the corner and protruding portions.

Additionally, or alternatively, a first distance between the selector 265 and the plug 253 may be different from (e.g., less than) a second distance between the selector 265 and the conductive material within the bit line structures 270. The difference in these distances may produce varying magnitudes of an electric field within the plug 253 and the bit line structures 270. For example, the electric field may be relatively weak within the bit line structures (e.g., in the connection region) or may be relatively strong within the plug 253. The varying electric field magnitudes may reduce current flow, increase resistance, and reduce efficiency overall, among other examples.

Techniques described herein provide for a plug structure that protects against backside source diffusion while maintaining efficient and reliable current flow via the bit line structures. For example, one or more voltage lines as described herein may be positioned above or otherwise around the selector 265. The voltage lines may be configured to apply one or more voltages to the plug 253, which may improve the electric field consistency (e.g., by equalizing the first distance 261 with a third distance (not pictured) between a voltage line and the bit line structures), and may improve current through the protruding connection region, among other examples. The voltage lines are described and illustrated in further detail elsewhere herein, including with reference to FIGS. 3 and 4.

FIG. 3 shows an example of a memory architecture 300 that supports dummy word line positioning for a plug for protection of backside source formation of vertical planar memory cells in accordance with examples as disclosed herein. The memory architecture 300 may be an example of a portion of an apparatus (e.g., a memory system), such as an apparatus 100. FIG. 3 shows a cross-sectional view of a memory architecture 300, which may be an example of a memory architecture implemented by an apparatus 100, as described with reference to FIGS. 1 and 2. The memory architecture 300 may illustrate a result of one or more operations associated with forming a stack of materials 305 including at least a first level 310, a second level 315, a conductive plug 353, conductive material 350, and a selector 365, among other materials and components described with reference to FIGS. 2A through 2I. In this example, the memory architecture 300 may include one or more voltage lines 380 in addition to the selector 365.

The stack of materials may be included in an apparatus including memory cells across one or more levels of the apparatus that are connected with respective bit lines. Performing the processing steps may consolidate processing steps otherwise associated with forming a memory architecture. For example, the processing steps may support reduced diffusion of a source material to unnecessary regions of an apparatus, among other advantages.

For illustrative purposes, aspects of the memory architecture 300 may be described with reference to an x-direction, a y-direction, and a z-direction of the illustrated coordinate systems. For example, the memory architecture 300 illustrates the memory architecture from a cross-sectional and/or planar view, such that a portion of the memory architecture may be removed from a trimetric view to illustrate a cross-section of the memory architecture 300 in the xz-plane. Although the memory architecture 300 illustrates examples of relative dimensions and quantities of various features, aspects of the memory architecture 300 may be implemented with other relative dimensions or quantities of such features in accordance with examples as disclosed herein. In the following description of the processing steps, some methods, techniques, processes, and operations may be performed in different orders or at different times. Further, some operations may be left out of the processing steps, or other operations may be added to the processing steps. Although described as singular processing steps, it is to be understood that each processing step may include one or more multiple processing operations, including, but not limited to, formations, depositions, etches, removals, exhumes, other processing steps, or the like.

Processing steps illustrated in and described with reference to FIG. 3 may be performed by a manufacturing system, such as a semiconductor fabrication system configured to perform additive operations such as deposition, formation, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

The memory architecture 300 may be formed by one or more processing steps described herein. The processing steps may represent examples of the processing steps described with reference to FIGS. 2A through 2I. In some examples, however, the techniques described herein may include forming the first level 310 of the stack of materials 305 to include more than one layer of the sacrificial material (e.g., the sacrificial material 202 described with reference to FIGS. 2A through 2F). For example, the first level 310 may include three layers of the sacrificial material, or some other quantity of layers that alternate with layers of the oxide material 303. The additional layers of the sacrificial material may be deposited prior to the formation of a sacrificial plug, such as the sacrificial plug 220 described with reference to FIG. 2A. The additional layers of the sacrificial material may or may not increase a size (e.g., height) of the first level 310.

The sacrificial plug may subsequently be formed in the first level 310, as described in further detail elsewhere herein, including with reference to FIG. 2A. The second level 315 may be formed on top of the sacrificial plug and the first level 310, and a cavity 335 may be formed through the second level 315. The sacrificial plug may be removed via the cavity 335 and various layers of materials may be formed in the cavity 335 and a first cavity left by removal of the sacrificial plug, as described with reference to FIG. 2C. For example, a first protective liner 345, a storage material 390, and a second protective liner 340 may be formed along sidewalls of the stack of materials 305 within the cavities.

The conductive material 350 may subsequently be formed on top of the layers of the materials. The conductive material 350 may form the conductive plug 353 that extends (e.g., in a rectangular shape) in the z and y-directions within the first level 310. The conductive material 350 may further include a first segment 351 that extends horizontally (e.g., in the x-direction) from the conductive plug 353 and a second segment 352 that extends vertically (e.g., in the z-direction) from the second segment 352 and along sidewalls of the stack of materials 305 within the cavity 335. A channel oxide material 355 may be formed on top of the conductive material 350 within the cavity 335.

As described in further detail elsewhere herein, including with reference to FIGS. 2E through 2G, the conductive material 350 and the channel oxide material 355 may be etched to form segments of conductive material that are separated (e.g., isolated) from one another in the y-direction. The segments may each represent an example of a bit line structure (e.g., the bit line structures 270 in FIG. 2G).

After the bit line structures are formed, the apparatus may undergo a metallization process, as described with reference to FIG. 2H. For example, the sacrificial material may be replaced with a metal material 304. The layers of metal material 304 in the second level 315 may ultimately form word lines for accessing memory cells 105 in the apparatus. The layers of the metal material 304 in the first level 310 may form a selector 365, one or more voltage lines 380, or some other type of conductive line. A backside source formation operation may be performed, in which the source 360 is formed. The conductive plug 353 may protect the remainder of the memory architecture from source diffusion during the source formation, as described in further detail with reference to FIG. 2H. The source 360, the conductive plug 353, and the selector 365 may collectively form a transistor or other selection component for activating the plug and initiating current flow via the bit line structures.

The selector 365 (e.g., an SGS-GG) may be configured to apply a first voltage to a memory channel including the conductive material 350 and the storage material 390, which may induce current flow (e.g., GIDL). In some examples, the induced current may be relatively low through the recessed region 336 due to, for example, the shape of the materials within the recessed region 336. For example, the protruding portions of material and sharp corners may increase resistance. If a threshold voltage associated with a first word line in the second level 315 of the stack of materials 305 is reduced (e.g., a lower SGS1 voltage threshold), the induced current may increase. As such, there may be one or more issues associated with an electric field 395 in the recessed region 336 due to the relative positioning between the selector 365 and the first word line if no voltage lines are included. Additionally, or alternatively, the selector 365 may not be able to control the memory channel at a corner within the recessed region 336, in some cases.

The techniques described herein provide for inclusion of the voltage lines 380-a and 380-b (e.g., any quantity of one or more voltage lines 380) to improve the consistency and continuity of the electric field 395 within the memory channel. The voltage lines 380 may be referred to as dummy word lines, in some examples described herein. The voltage lines 380 may each have an independent voltage, which may be configured to increase the string current and induced drain leakage by increasing the electric field 395.

A voltage applied to one or more of the voltage lines 380 may be equal to a first voltage applied to the selector 365 (e.g., Vgg) and an offset voltage, which may be some constant or other voltage value (e.g., V_{dummy}=Vgg±5V, or some other offset value). The applied voltage may increase the electric field 395 within the recessed region 336, resulting in improved current flow.

If the apparatus receives an access command to access one of the memory cells 105-f, 105-g, 105-h, the apparatus may utilize the selector 365, the voltage lines 380, and the word lines including the metal material 304 to access the requested memory cell. For example, to access the memory cell 105-f, the apparatus may apply a first voltage to a first word line that is coupled with or at least at a same layer as the memory cell 105-f (e.g., a top word line in the second level 315 in FIG. 3). The apparatus may activate one or more bit line structures (e.g., string lines) that are coupled with the memory cell 105-f by applying a second voltage to the selector 365 and applying one or more third voltages to the voltage lines 380-a and/or 380-b. The selector 365 and the voltage lines 380-a and 380-b may be coupled with the conductive plug 353. The applied second and one or more third voltages may thereby induce an electric field 395 within the conductive plug 353 and the corresponding bit line structures (e.g., string line selectors). In some examples, one or more bit lines (e.g., bit lines 155) may be extend in the x-direction or the y-direction above the stack of materials 305 and may be coupled with one or more of the bit line structures (e.g., each bit line structure may be coupled with a respective bit line). The bit lines may additionally, or alternatively, be activated to access a respective memory cell 105.

A magnitude of the one or more third voltages may be based on a magnitude of the second voltage applied to the selector 365. For example, the magnitude of the one or more third voltages may be offset from the magnitude of the second voltage (e.g., a positive or negative offset) so as to produce the largest electric field 395. The voltage offset may be based on a quantity of voltage lines 380 that are within the apparatus, that are used for access operations, or any combination thereof. Additionally, or alternatively, the magnitude of the one or more third voltages may be based on a physical positioning of the one or more voltage lines 380 (e.g., a distance between the voltage lines 380 and the selector 365, a distance between the voltage lines 380 and the bit line structures, whether the voltage lines 380 are positioned above or below the selector 365, and the like). A voltage applied to the voltage line 380-a may be the same as or different form a voltage applied to the voltage line 380-b based on one or more parameters associated with the voltage lines 380 being different (e.g., a size, distance, shape, or the like).

The apparatus may apply the first through third voltages in any order or at least partially concurrently. The apparatus may access the logic state stored by the memory cell 105-f based on activating the selector 365, the voltage lines 380-a and 380-b, and the first word line. The use of the voltage lines 380-a and 380-b may improve the current flow during the access operation, which may improve efficiency and reliability of the operation as compared with using the selector 365 without the voltage lines 380. For example, a magnitude and/or direction of the current flow through a memory channel may be based on the voltages applied to the one or more voltage lines 380.

FIG. 4 shows an example of a memory architecture 400 that supports dummy word line positioning for a plug for protection of backside source formation of vertical planar memory cells in accordance with examples as disclosed herein. The memory architecture 400 may be an example of a portion of an apparatus, such as an apparatus 100. FIG. 4 shows a cross-sectional view of a memory architecture 400, which may be an example of a memory architecture implemented by an apparatus 100, as described with reference to FIGS. 1 through 3. The memory architecture 400 may illustrate a result of one or more operations associated with forming a stack of materials 405 including at least a first level 410, a second level 415, a conductive plug 453, conductive material 450, and a selector 465, among other materials and components described with reference to FIGS. 2A through 2I. In this example, the memory architecture 400 may include one or more voltage lines 480 in addition to the selector 465.

The stack of materials may be included in an apparatus including memory cells across one or more levels of the apparatus that are connected with respective bit lines. Performing the processing steps may consolidate processing steps otherwise associated with forming a memory architecture. For example, the processing steps may support reduced diffusion of a source material to unnecessary regions of an apparatus, among other advantages.

For illustrative purposes, aspects of the memory architecture 400 may be described with reference to an x-direction, a y-direction, and a z-direction of the illustrated coordinate systems. For example, the memory architecture 400 illustrates the memory architecture from a cross-sectional and/or planar view, such that a portion of the memory architecture may be removed from a trimetric view to illustrate a cross-section of the memory architecture 400 in the xz-plane. Although the memory architecture 400 illustrates examples of relative dimensions and quantities of various features, aspects of the memory architecture 400 may be implemented with other relative dimensions or quantities of such features in accordance with examples as disclosed herein. In the following description of the processing steps, some methods, techniques, processes, and operations may be performed in different orders or at different times. Further, some operations may be left out of the processing steps, or other operations may be added to the processing steps. Although described as singular processing steps, it is to be understood that each processing step may include one or more multiple processing operations, including, but not limited to, formations, depositions, etches, removals, exhumes, other processing steps, or the like.

Processing steps illustrated in and described with reference to FIG. 4 may be performed by a manufacturing system, such as a semiconductor fabrication system configured to perform additive operations such as deposition, formation, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

The memory architecture 400 may be formed by one or more processing steps described herein. The processing steps may represent examples of the processing steps described with reference to FIGS. 2A through 2I. In some examples, however, the techniques described herein may include forming the first level 410 of the stack of materials 405 to include more than one layer of the sacrificial material (e.g., the sacrificial material 202 described with reference to FIGS. 2A through 2F). For example, the first level 410 may include three layers of the sacrificial material, or some other quantity of layers that alternate with layers of the oxide material 403. The additional layers of the sacrificial material may be deposited prior to the formation of a sacrificial plug, such as the sacrificial plug 220 described with reference to FIG. 2A. The additional layers of the sacrificial material may or may not increase a size (e.g., height) of the first level 410.

The sacrificial plug may subsequently be formed in the first level 410, as described in further detail elsewhere herein, including with reference to FIG. 2A. In this example, the sacrificial plug may be formed with a rounded top portion. For example, a top portion of the sacrificial plug may have a double U-shape, or some other curvy shape with a flat or planar top surface. The second level 415 may be formed on top of the sacrificial plug and the first level 410, and a cavity 435 may be formed through the second level 415. The sacrificial plug may be removed via the cavity 435 and various layers of materials may be formed in the cavity 435 and a first cavity left by removal of the sacrificial plug, as described with reference to FIG. 2C. For example, a first protective liner 445, a storage material 490, and a second protective liner 440 may be formed along sidewalls of the stack of materials 405 within the cavities. The shape of the sidewalls and corresponding materials may be similar to the shape of the sacrificial plug. The materials may thereby include one or more curved or otherwise rounded sidewalls. In some examples, the second protective liner 440 may include one or more sharp corners on one side, but may be relatively round and smooth on a side that is closest to the cavity 435.

The conductive material 450 may subsequently be formed on top of the layers of the materials. The conductive material 450 may form the conductive plug 453 that extends (e.g., in a rectangular shape) in the z and y-directions within the first level 410. The conductive material 450 may further include a first segment 451 that extends horizontally (e.g., in the x-direction) from the conductive plug 453 and a second segment 452 that extends vertically (e.g., in the z-direction) along sidewalls of the stack of materials 405 within the cavity 435. The conductive material 450 may include a third segment 454 that connects the first segment 451 to the second segment 452 via one or more curvatures (e.g., a double U-shape or a double C-shape, or some other rounded shape). A channel oxide material 455 may be formed on top of the conductive material 450 within the cavity 435. The conductive material 450 may be associated with reduced resistance due to, for example, the rounded and curved connection region instead of sharp or pointing connection corners.

As described in further detail elsewhere herein, including with reference to FIGS. 2E through 2G, the conductive material 450 and the channel oxide material 455 may be etched to form segments of conductive material that are separated (e.g., isolated) from one another in the y-direction. The segments may each represent an example of a bit line (e.g., the bit line structures 270 in FIG. 2G).

After the bit line structures are formed, the apparatus may undergo a metallization process, as described with reference to FIG. 2H. For example, the sacrificial material may be replaced with a metal material 404. The layers of metal material 404 in the second level 415 may ultimately form word lines for accessing memory cells 105 in the apparatus. The layers of the metal material 404 in the first level 410 may form a selector 465, one or more voltage lines 480, or some other type of conductive line. A backside source formation operation may be performed, in which the source 460 is formed. The conductive plug 453 may protect the remainder of the memory architecture from source diffusion during the source formation, as described in further detail with reference to FIG. 2H. The source 460, the conductive plug 453, and the selector 465 may collectively form a transistor or other selection component for activating the plug and initiating current flow via the bit line structures.

The selector 465 (e.g., an SGS-GG) may be configured to apply a first voltage to a memory channel including the conductive material 450 and the storage material 490, which may induce current flow (e.g., GIDL). In some examples, the induced current may be relatively low through the recessed region 436 due to, for example, the shape of the materials within the recessed region 436. However, the curved structure of the sacrificial plug may improve the shape and thereby reduce resistance. For example, as illustrated in FIG. 4, the conductive material 450 may be rounded throughout the recessed region 436 and may have curves instead of corners or sharp edges, which may reduce resistance throughout.

As described with reference to FIG. 2H, in some examples, if an apparatus includes a selector and no voltage lines, a first distance between the selector and an edge of the memory channel may be different from a second distance between the selector and an edge of the bit line structures (e.g., the distances 261 and 262 in FIG. 2H). The differing distances may produce different electric fields in different regions of the memory channel. For example, an electric field in the conductive plug 453 may be stronger than needed and an electric field in the bit line structures may be weaker than needed, which may reduce current flow.

The techniques described herein provide for positioning of the voltage lines 480 such that a first distance 461 between a top-most voltage line 480-a and the conductive material 450 in the conductive plug 453 (e.g., an edge of the memory channel) is the same as (e.g., or nearly the same as) a second distance 462 between the top-most voltage line 480-a and the conductive material 450 in the bit line structures (e.g., another edge of the memory channel).

If the first distance 461 and the second distance 462 are the same or within a threshold difference of each other, the electric field within the memory channel may be relatively consistent throughout, which may improve efficiency and current flow. Such a structure may increase string current without a risk of breakdown, which may occur by, for example, creating an electric field that is above a threshold in a first local region (e.g., in the conductive plug 453) to obtain sufficient string current.

The voltage lines 480-a and 480-b (e.g., any quantity of one or more voltage lines 480) may thereby be included in the memory architecture 400 at certain physical positions relative to the memory channel to improve the consistency and continuity of the electric field within the memory channel. The positioning of the voltage lines 480 may be based on formation of the sacrificial material layers in the first level 410 of the stack of materials 405. For example, a top layer of sacrificial material may be formed nearer to the top surface of the first level 410 than in other structures, such that the top portion of the sacrificial plug creates a cavity that extends to a top surface of the sacrificial material. The voltage lines 480 may be referred to as dummy word lines, in some examples described herein.

As described with reference to FIG. 3, the voltage lines 480 may each have an independent voltage, which may be configured to increase the string current and induced drain leakage by increasing the electric field. In some examples, the voltages applied to each voltage line 480 and to the selector 465 may be calculated such that the electric field remains constant throughout the conductive plug 453 and the bit line structures.

The apparatus may thereby apply a first voltage to a word line (e.g., layer of the metal material 404), a second voltage to the selector 465, and one or more third voltages to the one or more voltage lines 480 to access a given memory cell in response to an access command, as described in further detail elsewhere herein, including with reference to FIG. 3.

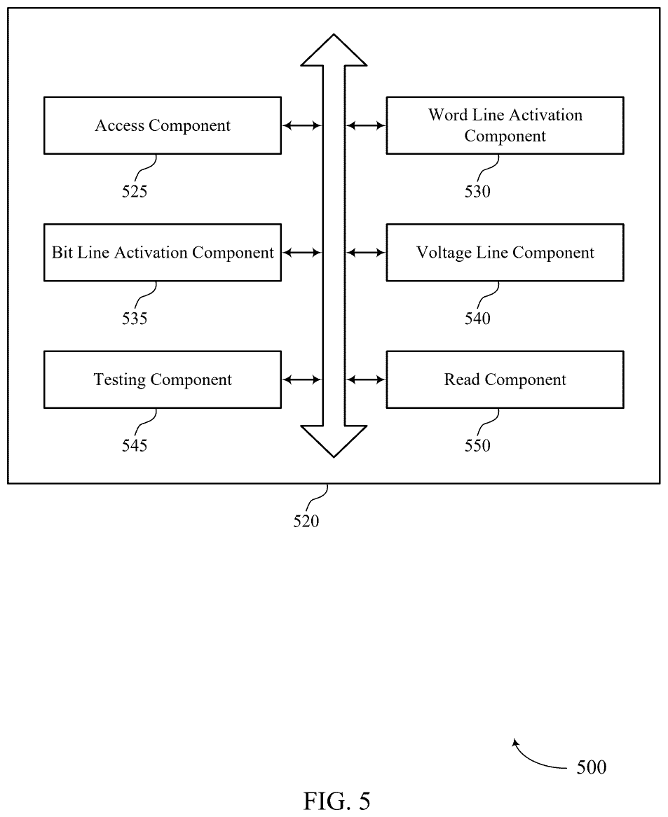

FIG. 5 shows a block diagram 500 of a memory system 520 that supports dummy word line positioning for a plug for protection of backside source formation of vertical planar memory cells in accordance with examples as disclosed herein. The memory system 520 may be an example of aspects of a memory system as described with reference to FIGS. 1 through 4. The memory system 520, or various components thereof, may be an example of means for performing various aspects of dummy word line positioning for a plug for protection of backside source formation of vertical planar memory cells as described herein. For example, the memory system 520 may include an access component 525, a word line activation component 530, a bit line activation component 535, a voltage line component 540, a testing component 545, a read component 550, or any combination thereof. Each of these components, or components of subcomponents thereof (e.g., one or more processors, one or more memories), may communicate, directly or indirectly, with one another (e.g., via one or more buses).

The access component 525 may be configured as or otherwise support a means for receiving a request to access one or more memory cells of a plurality of memory cells of the memory system, where the one or more memory cells are positioned in a first layer of a plurality of layers of memory cell pillars within the memory system. The word line activation component 530 may be configured as or otherwise support a means for applying, based at least in part on the request, a first voltage to a first word line of a plurality of word lines of the memory system, the first word line positioned within the first layer of the memory system. The bit line activation component 535 may be configured as or otherwise support a means for activating, based at least in part on the request, one or more bit line structures of the memory system using a selector and one or more voltage lines, where the one or more bit line structures extend in a first direction through a first subset of layers of the plurality of layers, the first subset of layers including at least the first layer. In some examples, to activate the one or more bit line structures, the bit line activation component 535 may be configured as or otherwise support a means for applying a second voltage to the selector of the memory system, where the selector is coupled with a plug of conductive material that extends, in a first direction, through a second subset of layers of the plurality of layers, the second subset of layers positioned below the plurality of memory cells and the first subset of layers relative to a substrate of the memory system, the plug in contact with the one or more bit line structures. In some examples, to activate the one or more bit line structures, the bit line activation component 535 may be configured as or otherwise support a means for applying one or more third voltages to the one or more voltage lines of the memory system, where the one or more voltage lines are coupled with the plug within the second subset of layers of the plurality of layers, and where a magnitude of the one or more third voltages is based at least in part on the second voltage. In some examples, the bit line activation component 535 may be configured as or otherwise support a means for accessing the one or more memory cells based at least in part on applying the first voltage to the first word line and activating the one or more bit line structures.

In some examples, the voltage line component 540 may be configured as or otherwise support a means for determining a value of the one or more third voltages based at least in part on a value of the second voltage and a voltage offset.

In some examples, the voltage offset is based at least in part on a quantity of voltage lines included in the one or more voltage lines of the memory system.

In some examples, to support applying the one or more third voltages to the one or more voltage lines, the voltage line component 540 may be configured as or otherwise support a means for applying a third voltage to a first voltage line of the one or more voltage lines. In some examples, to support applying the one or more third voltages to the one or more voltage lines, the voltage line component 540 may be configured as or otherwise support a means for applying a fourth voltage to a second voltage line of the one or more voltage lines, where a fourth value of the fourth voltage is different from a third value of the third voltage.

In some examples, to support applying the one or more third voltages to the one or more voltage lines, the voltage line component 540 may be configured as or otherwise support a means for applying a third voltage having a third voltage value to each voltage line of the one or more voltage lines.

In some examples, the testing component 545 may be configured as or otherwise support a means for performing one or more testing operations to access the plurality of memory cells, where a first value of the second voltage and one or more second values of the one or more third voltages are based at least in part on electric fields within a memory channel between the selector and the plurality of memory cells during the one or more testing operations.

In some examples, to support accessing the one or more memory cells, the read component 550 may be configured as or otherwise support a means for reading or programming one or more logic states stored within the one or more memory cells based at least in part on a current through the one or more bit line structures and the one or more memory cells, where a magnitude of the current is based at least in part on a combination of the second voltage and the one or more third voltages.

In some examples, the described functionality of the memory system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 520, or various components thereof, may be implemented at least in part by instructions (e.g., stored in memory, non-transitory computer-readable medium) executable by such at least one processor.

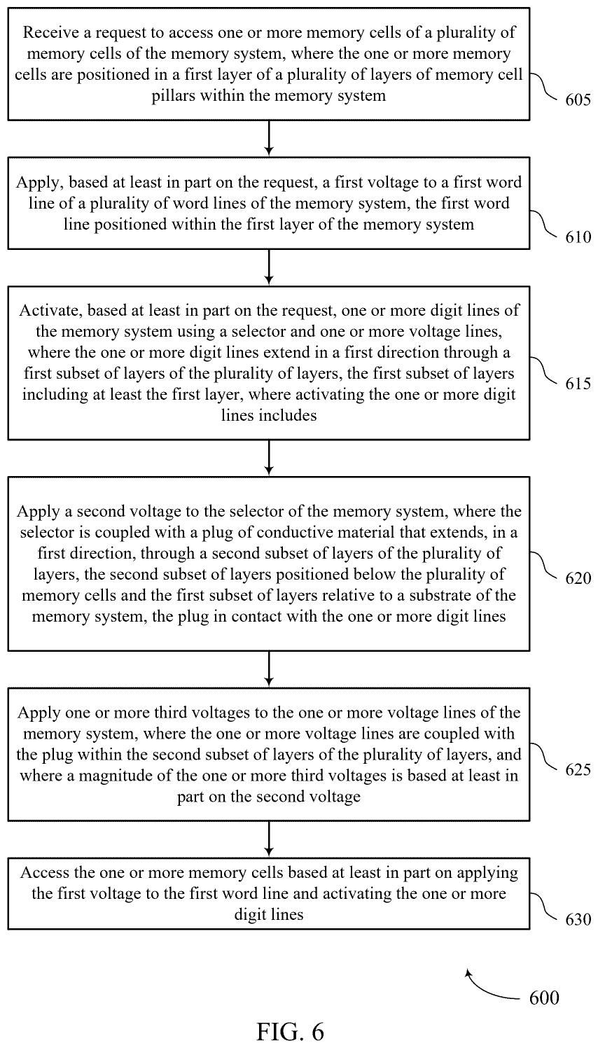

FIG. 6 shows a flowchart illustrating a method 600 that supports dummy word line positioning for a plug for protection of backside source formation of vertical planar memory cells in accordance with examples as disclosed herein. The operations of method 600 may be implemented by a memory system or its components as described herein. For example, the operations of method 600 may be performed by a memory system (e.g., apparatus) as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the method may include receiving a request to access one or more memory cells of a plurality of memory cells of the memory system, where the one or more memory cells are positioned in a first layer of a plurality of layers of memory cell pillars within the memory system. In some examples, aspects of the operations of 605 may be performed by an access component 525 as described with reference to FIG. 5.

At 610, the method may include applying, based at least in part on the request, a first voltage to a first word line of a plurality of word lines of the memory system, the first word line positioned within the first layer of the memory system. In some examples, aspects of the operations of 610 may be performed by a word line activation component 530 as described with reference to FIG. 5.

At 615, the method may include activating, based at least in part on the request, one or more bit line structures of the memory system using a selector and one or more voltage lines, where the one or more bit line structures extend in a first direction through a first subset of layers of the plurality of layers, the first subset of layers including at least the first layer. In some examples, aspects of the operations of 615 may be performed by a bit line activation component 535 as described with reference to FIG. 5.

At 620, to activate the one or more bit line structures, the method may include applying a second voltage to the selector of the memory system, where the selector is coupled with a plug of conductive material that extends, in a first direction, through a second subset of layers of the plurality of layers, the second subset of layers positioned below the plurality of memory cells and the first subset of layers relative to a substrate of the memory system, the plug in contact with the one or more bit line structures. In some examples, aspects of the operations of 620 may be performed by a bit line activation component 535 as described with reference to FIG. 5.

At 625, to activate the one or more bit line structures, the method may include applying one or more third voltages to the one or more voltage lines of the memory system, where the one or more voltage lines are coupled with the plug within the second subset of layers of the plurality of layers, and where a magnitude of the one or more third voltages is based at least in part on the second voltage. In some examples, aspects of the operations of 625 may be performed by a bit line activation component 535 as described with reference to FIG. 5.

At 630, the method may include accessing the one or more memory cells based at least in part on applying the first voltage to the first word line and activating the one or more bit line structures. In some examples, aspects of the operations of 630 may be performed by a bit line activation component 535 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving a request to access one or more memory cells of a plurality of memory cells of the memory system, where the one or more memory cells are positioned in a first layer of a plurality of layers of memory cell pillars within the memory system; applying, based at least in part on the request, a first voltage to a first word line of a plurality of word lines of the memory system, the first word line positioned within the first layer of the memory system; activating, based at least in part on the request, one or more bit line structures of the memory system using a selector and one or more voltage lines, where the one or more bit line structures extend in a first direction through a first subset of layers of the plurality of layers, the first subset of layers including at least the first layer, where activating the one or more bit line structures includes: applying a second voltage to the selector of the memory system, where the selector is coupled with a plug of conductive material that extends, in a first direction, through a second subset of layers of the plurality of layers, the second subset of layers positioned below the plurality of memory cells and the first subset of layers relative to a substrate of the memory system, the plug in contact with the one or more bit line structures; applying one or more third voltages to the one or more voltage lines of the memory system, where the one or more voltage lines are coupled with the plug within the second subset of layers of the plurality of layers, and where a magnitude of the one or more third voltages is based at least in part on the second voltage; and accessing the one or more memory cells based at least in part on applying the first voltage to the first word line and activating the one or more bit line structures.

Aspect 2: The method, apparatus, or non-transitory computer-readable medium of aspect 1, further including operations, features, circuitry, logic, means, or instructions, or any combination thereof for determining a value of the one or more third voltages based at least in part on a value of the second voltage and a voltage offset.

Aspect 3: The method, apparatus, or non-transitory computer-readable medium of aspect 2, where the voltage offset is based at least in part on a quantity of voltage lines included in the one or more voltage lines of the memory system.

Aspect 4: The method, apparatus, or non-transitory computer-readable medium of any of aspects 1 through 3, where applying the one or more third voltages to the one or more voltage lines includes operations, features, circuitry, logic, means, or instructions, or any combination thereof for applying a third voltage to a first voltage line of the one or more voltage lines and applying a fourth voltage to a second voltage line of the one or more voltage lines, where a fourth value of the fourth voltage is different from a third value of the third voltage.

Aspect 5: The method, apparatus, or non-transitory computer-readable medium of any of aspects 1 through 4, where applying the one or more third voltages to the one or more voltage lines includes operations, features, circuitry, logic, means, or instructions, or any combination thereof for applying a third voltage having a third voltage value to each voltage line of the one or more voltage lines.

Aspect 6: The method, apparatus, or non-transitory computer-readable medium of any of aspects 1 through 5, further including operations, features, circuitry, logic, means, or instructions, or any combination thereof for performing one or more testing operations to access the plurality of memory cells, where a first value of the second voltage and one or more second values of the one or more third voltages are based at least in part on electric fields within a memory channel between the selector and the plurality of memory cells during the one or more testing operations.

Aspect 7: The method, apparatus, or non-transitory computer-readable medium of any of aspects 1 through 6, where accessing the one or more memory cells includes operations, features, circuitry, logic, means, or instructions, or any combination thereof for reading or programming one or more logic states stored within the one or more memory cells based at least in part on a current through the one or more bit line structures and the one or more memory cells, where a magnitude of the current is based at least in part on a combination of the second voltage and the one or more third voltages.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 8: An apparatus, including: a stack including a plurality of oxide layers and a plurality of metal layers, the stack including a first level and a second level, the first level positioned below the second level in a first direction; a plug passing through the first level of the stack in the first direction and extending in a second direction within the stack; a plurality of bit line structures extending from the plug through the second level of the stack, where each bit line structure of the plurality of bit line structures is coupled with the plug and is physically isolated from other bit line structures of the plurality of bit line structures; a selector within a first metal layer, of the plurality of metal layers, that is in the first level of the stack, where the selector is configured to apply a voltage to the plurality of bit line structures via the plug, the plug extending through a portion of the first metal layer that includes the selector; one or more voltage lines within one or more second metal layers, of the plurality of metal layers, in the first level of the stack, where the one or more voltage lines are configured to apply a voltage offset to the plurality of bit line structures via the plug, the plug extending through a portion of the one or more second metal layers that include the one or more voltage lines; and a plurality of memory cells positioned in the second level of the stack.

Aspect 9: The apparatus of aspect 8, further including: a channel having a width and including a memory material, where the channel extends between the plug and the first level of the stack and between the plurality of bit line structures and the second level of the stack, and where the width is equal to a distance between a top surface of a first voltage line of the one or more voltage lines and a top surface of the channel within a connection portion of the channel.

Aspect 10: The apparatus of aspect 9, where: the connection portion of the channel includes at least two curved segments that curve along concave sidewalls of the stack between a first straight sidewall of the stack in the first level and a second straight sidewall of the stack in the second level; and the distance is between the top surface of the first voltage line and a top surface of a straight segment of the channel that is between the at least two curved segments of the channel within the connection portion.

Aspect 11: The apparatus of any of aspects 9 through 10, where the channel includes: a first portion that extends, in the first direction, through the first level of the stack and is in contact with the plug; a second portion that extends, in the first direction, through the second level of the stack and is in contact with the plurality of bit line structures; and the connection portion that extends, in the first direction, a third direction, or both, between the first portion and the second portion of the channel.

Aspect 12: The apparatus of any of aspects 9 through 11, where the channel includes: one or more liners that extend along sidewalls of the channel; and the memory material that extends between the one or more liners within the channel.

Aspect 13: The apparatus of any of aspects 8 through 12, where: each bit line structure of the plurality of bit line structures includes a first segment and a second segment of conductive material, the first segment extends, in a third direction, from a top surface of the plug to the second segment, and the second segment extends, in the first direction, from the first segment to a top layer of the stack.

Aspect 14: The apparatus of aspect 13, where respective first segments of the plurality of bit line structures are parallel to the one or more voltage lines.

Aspect 15: The apparatus of any of aspects 8 through 14, where: each bit line structure of the plurality of bit line structures includes a first segment and a second segment of conductive material; the first segment curves, in the first direction and a third direction, from a top surface of the plug to the second segment; and the second segment extends, in the first direction, from the first segment to a top layer of the stack.

Aspect 16: The apparatus of any of aspects 8 through 15, where: the plurality of bit line structures includes a first subset of bit line structures and a second subset of bit line structures, the first subset of bit line structures including bit line structures that extend along a first axis in the second direction, and the second subset of bit line structures including bit line structures that extend along a second axis in the second direction, and the plug is between the first axis and the second axis in a third direction.

Aspect 17: The apparatus of any of aspects 8 through 16, where the plug includes a pillar of oxide material and conductive material that is in contact with at least two sidewalls of the pillar of oxide material.

Aspect 18: The apparatus of any of aspects 8 through 17, further including: a plurality of oxide liners that each extend along a top surface of a respective bit line structure of the plurality of bit line structures.

Aspect 19: The apparatus of any of aspects 8 through 18, where one or more metal layers, of the plurality of metal layers, that are within the second level of the stack, include word lines.

An apparatus is described. The following provides an overview of aspects of the apparatus as described herein:

Aspect 20: A memory system, including: one or more memory devices; and processing circuitry coupled with the one or more memory devices and configured to cause the memory system to: receive a request to access one or more memory cells of a plurality of memory cells of the memory system, where the one or more memory cells are positioned in a first layer of a plurality of layers of memory cell pillars within the memory system; apply, based at least in part on the request, a first voltage to a first word line of a plurality of word lines of the memory system, the first word line positioned within the first layer of the memory system; activate, based at least in part on the request, one or more bit line structures of the memory system using a selector and one or more voltage lines, where the one or more bit line structures extend in a first direction through a first subset of layers of the plurality of layers, the first subset of layers including at least the first layer, where, to activate the one or more bit line structures, the processing circuitry is configured to: apply a second voltage to the selector of the memory system, where the selector is coupled with a plug of conductive material that extends, in a first direction, through a second subset of layers of the plurality of layers, the second subset of layers positioned below the plurality of memory cells and the first subset of layers relative to a substrate of the memory system, the plug in contact with the one or more bit line structures; and apply one or more third voltages to the one or more voltage lines of the memory system, where the one or more voltage lines are coupled with the plug within the second subset of layers of the plurality of layers, and where a magnitude of the one or more third voltages is based at least in part on the second voltage; and access the one or more memory cells based at least in part on applying the first voltage to the first word line and activating the one or more bit line structures.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a stack comprising a plurality of oxide layers and a plurality of metal layers, the stack comprising a first level and a second level, the first level positioned below the second level in a first direction;
a plug passing through the first level of the stack in the first direction and extending in a second direction within the stack;
a plurality of bit line structures extending from the plug through the second level of the stack, wherein each bit line structure of the plurality of bit line structures is coupled with the plug and is physically isolated from other bit line structures of the plurality of bit line structures;
a selector within a first metal layer, of the plurality of metal layers, that is in the first level of the stack, wherein the selector is configured to apply a voltage to the plurality of bit line structures via the plug, the plug extending through a portion of the first metal layer that comprises the selector;
one or more voltage lines within one or more second metal layers, of the plurality of metal layers, in the first level of the stack, wherein the one or more voltage lines are configured to apply a voltage offset to the plurality of bit line structures via the plug, the plug extending through a portion of the one or more second metal layers that comprise the one or more voltage lines; and
a plurality of memory cells positioned in the second level of the stack.

2. The apparatus of claim 1, further comprising:
a channel having a width and comprising a memory material, wherein the channel extends between the plug and the first level of the stack and between the plurality of bit line structures and the second level of the stack, and wherein the width is equal to a distance between a top surface of a first voltage line of the one or more voltage lines and a top surface of the channel within a connection portion of the channel.

3. The apparatus of claim 2, wherein:
the connection portion of the channel comprises at least two curved segments that curve along concave sidewalls of the stack between a first straight sidewall of the stack in the first level and a second straight sidewall of the stack in the second level; and
the distance is between the top surface of the first voltage line and a top surface of a straight segment of the channel that is between the at least two curved segments of the channel within the connection portion.

4. The apparatus of claim 2, wherein the channel comprises:
a first portion that extends, in the first direction, through the first level of the stack and is in contact with the plug;
a second portion that extends, in the first direction, through the second level of the stack and is in contact with the plurality of bit line structures; and
the connection portion that extends, in the first direction, a third direction, or both, between the first portion and the second portion of the channel.

5. The apparatus of claim 2, wherein the channel comprises:
one or more liners that extend along sidewalls of the channel; and
the memory material that extends between the one or more liners within the channel.

6. The apparatus of claim 1, wherein:
each bit line structure of the plurality of bit line structures comprises a first segment and a second segment of conductive material,
the first segment extends, in a third direction, from a top surface of the plug to the second segment, and
the second segment extends, in the first direction, from the first segment to a top layer of the stack.

7. The apparatus of claim 6, wherein respective first segments of the plurality of bit line structures are parallel to the one or more voltage lines.

8. The apparatus of claim 1, wherein:
each bit line structure of the plurality of bit line structures comprises a first segment and a second segment of conductive material;
the first segment curves, in the first direction and a third direction, from a top surface of the plug to the second segment; and
the second segment extends, in the first direction, from the first segment to a top layer of the stack.

9. The apparatus of claim 1, wherein:
the plurality of bit line structures comprises a first subset of bit line structures and a second subset of bit line structures, the first subset of bit line structures comprising bit line structures that extend along a first axis in the second direction, and the second subset of bit line structures comprising bit line structures that extend along a second axis in the second direction, and
the plug is between the first axis and the second axis in a third direction.

10. The apparatus of claim 1, wherein the plug comprises a pillar of oxide material and conductive material that is in contact with at least two sidewalls of the pillar of oxide material.

11. The apparatus of claim 1, further comprising:
a plurality of oxide liners that each extend along a top surface of a respective bit line structure of the plurality of bit line structures.

12. The apparatus of claim 1, wherein one or more metal layers, of the plurality of metal layers, that are within the second level of the stack, comprise word lines.

13. A method at a memory system, comprising:
receiving a request to access one or more memory cells of a plurality of memory cells of the memory system, wherein the one or more memory cells are positioned in a first layer of a plurality of layers of memory cell pillars within the memory system;
applying, based at least in part on the request, a first voltage to a first word line of a plurality of word lines of the memory system, the first word line positioned within the first layer of the memory system;
activating, based at least in part on the request, one or more bit line structures of the memory system using a selector and one or more voltage lines, wherein the one or more bit line structures extend in a first direction through a first subset of layers of the plurality of layers, the first subset of layers comprising at least the first layer, wherein activating the one or more bit line structures comprises:
applying a second voltage to the selector of the memory system, wherein the selector is coupled with a plug of conductive material that extends, in a first direction, through a second subset of layers of the plurality of layers, the second subset of layers positioned below the plurality of memory cells and the first subset of layers relative to a substrate of the memory system, the plug in contact with the one or more bit line structures; and
applying one or more third voltages to the one or more voltage lines of the memory system, wherein the one or more voltage lines are coupled with the plug within the second subset of layers of the plurality of layers, and wherein a magnitude of the one or more third voltages is based at least in part on the second voltage; and
accessing the one or more memory cells based at least in part on applying the first voltage to the first word line and activating the one or more bit line structures.

14. The method of claim 13, further comprising:
determining a value of the one or more third voltages based at least in part on a value of the second voltage and a voltage offset.

15. The method of claim 14, wherein the voltage offset is based at least in part on a quantity of voltage lines included in the one or more voltage lines of the memory system.

16. The method of claim 13, wherein applying the one or more third voltages to the one or more voltage lines comprises:
applying a third voltage to a first voltage line of the one or more voltage lines; and
applying a fourth voltage to a second voltage line of the one or more voltage lines, wherein a fourth value of the fourth voltage is different from a third value of the third voltage.

17. The method of claim 13, wherein applying the one or more third voltages to the one or more voltage lines comprises:
applying a third voltage having a third voltage value to each voltage line of the one or more voltage lines.

18. The method of claim 13, further comprising:
performing one or more testing operations to access the plurality of memory cells, wherein a first value of the second voltage and one or more second values of the one or more third voltages are based at least in part on electric fields within a memory channel between the selector and the plurality of memory cells during the one or more testing operations.

19. The method of claim 13, wherein accessing the one or more memory cells comprises:
reading or programming one or more logic states stored within the one or more memory cells based at least in part on a current through the one or more bit line structures and the one or more memory cells, wherein a magnitude of the current is based at least in part on a combination of the second voltage and the one or more third voltages.

20. A memory system, comprising:
one or more memory devices; and
processing circuitry coupled with the one or more memory devices and configured to cause the memory system to:
receive a request to access one or more memory cells of a plurality of memory cells of the memory system, wherein the one or more memory cells are positioned in a first layer of a plurality of layers of memory cell pillars within the memory system;
apply, based at least in part on the request, a first voltage to a first word line of a plurality of word lines of the memory system, the first word line positioned within the first layer of the memory system;
activate, based at least in part on the request, one or more bit line structures of the memory system using a selector and one or more voltage lines, wherein the one or more bit line structures extend in a first direction through a first subset of layers of the plurality of layers, the first subset of layers comprising at least the first layer, wherein, to activate the one or more bit line structures, the processing circuitry is configured to:
apply a second voltage to the selector of the memory system, wherein the selector is coupled with a plug of conductive material that extends, in a first direction, through a second subset of layers of the plurality of layers, the second subset of layers positioned below the plurality of memory cells and the first subset of layers relative to a substrate of the memory system, the plug in contact with the one or more bit line structures; and
apply one or more third voltages to the one or more voltage lines of the memory system, wherein the one or more voltage lines are coupled with the plug within the second subset of layers of the plurality of layers, and wherein a magnitude of the one or more third voltages is based at least in part on the second voltage; and
access the one or more memory cells based at least in part on applying the first voltage to the first word line and activating the one or more bit line structures.
